(19) United States
(12) Patent Application Publication
(10) Pub. No.: US 2011/0042552 A1
(43) Pub. Date: Feb. 24, 2011

(54) SOLID-STATE IMAGING DEVICE AND METHOD OF MANUFACTURING THE SAME

(76) Inventors: Shogo FURUYA, Yokohama-shi (JP); Hirofumi Yamashita, Kawasaki-shi (JP); Yusuke Kohyama, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/852,782

(22) Filed: Aug. 9, 2010

(30) Foreign Application Priority Data
Aug. 19, 2009 (JP) 2009-190309

(51) Int. Cl. H01L 27/14; H01L 31/18

(52) U.S. Cl. 250/208.1; 438/59; 257/E31.097

(57) ABSTRACT

According to one embodiment, a solid-state imaging device with an array arrangement of unit pixels including photoelectric conversion parts configured to generate signal charges by photoelectric conversion and a signal scanning circuit part, the signal scanning circuit part being provided on a second semiconductor layer different from a first semiconductor layer including the photoelectric conversion parts, the second semiconductor layer being stacked above the front side of the first semiconductor layer via an insulating film, and the first semiconductor layer being so configured that a pixel separation insulating film is buried in pixel boundary parts and read transistors configured to read signal charges generated by the photoelectric conversion parts are formed at the front side of the first semiconductor layer.

### CROSS-REFERENCE TO RELATED APPLICATIONS

This application is based upon and claims the benefit of priority from Japanese Patent Application No. 2009-190309, filed Aug. 19, 2009; the entire contents of which are incorporated herein by reference.

### FIELD

Embodiments described herein relate generally to a MOS solid-state imaging device with an improved pixel separation structure and a method of manufacturing the same.

### BACKGROUND

Solid-state imaging devices, such as CMOS sensors, have been used in a wide variety of applications, including digital still cameras, video cameras, and surveillance cameras. Recently, a back-illuminated solid-state imaging device has been proposed to suppress a decrease in the signal-to-noise ratio due to a decrease in the pixel size. In the device, light is caused to enter the back side of the silicon substrate opposite the front side where a signal scanning circuit and its interconnection layer have been formed. Therefore, light entering the pixels can reach a light-receiving region formed in the silicon layer without being impeded by the interconnection layer. Accordingly, this offers the advantage of realizing a high quantum efficiency even when pixels are very small.

However, a back-illuminated solid-state imaging device has the following problem. Incident light leaks into adjacent pixels because the incident light is not impeded by the interconnection layer. When pixels are miniaturized, the aperture pitches of microlenses and color filters decrease, which permits diffraction to take place particularly when light entering R pixels corresponding to the long-wavelength passes through the color filter. In this case, light obliquely entering the silicon light-receiving region goes toward adjacent pixels. When the light crosses the boundary between pixels and enters the adjacent pixels, it generates photoelectrons in the adjacent pixels, causing crosstalk, which permits color mixture to take place. Therefore, color reproducibility is deteriorated on the replay screen, which causes the problem of degrading the image quality.

In the field of MOS solid-state imaging devices, to prevent color mixture caused by light that enters obliquely, a method of forming a multilayer film so as to enclose photoelectric conversion parts and separating the adjacent photoelectric conversion parts from one another electrically has been proposed. However, it is difficult to directly apply this configuration to a back-illuminated solid-state imaging device which has a signal scanning circuit and others provided in a semiconductor layer different from the photoelectric conversion parts.

### BRIEF DESCRIPTION OF THE DRAWINGS

FIG. 1 is a block diagram showing an overall configuration of a MOS solid-state imaging device according to a first embodiment;

FIG. 2 shows a circuit configuration of a pixel array of the MOS solid-state imaging device of the first embodiment;

FIG. 3 is a plan view showing an arrangement of color filters in the MOS solid-state imaging device of the first embodiment;

FIG. 4 shows a first plane configuration of the pixel array of the MOS solid-state imaging device of the first embodiment;

FIG. 5 shows a second plane configuration of the pixel array of the MOS solid-state imaging device of the first embodiment;

FIG. 6 is a sectional view taken along line VI-VI of each of FIGS. 4 and 5;

FIG. 7 is a sectional view showing the configuration of a unit pixel in the MOS solid-state imaging device of the first embodiment; and

FIGS. 8A, 8B, 8C, 8D, 8E, 8F, 8G, 8H, 8I, 8J, 8K, 8L, 8M, and 8N are sectional views to explain the process of manufacturing a MOS solid-state imaging device according to a second embodiment.

### DETAILED DESCRIPTION

In general, according to one embodiment, there is provided a solid-state imaging device with an array arrangement of unit pixels including photoelectric conversion parts for generating signal charges by photoelectric conversion and a signal scanning circuit part, the signal scanning circuit part being provided on a second semiconductor layer different from a first semiconductor layer including the photoelectric conversion parts, the second semiconductor layer being stacked above the front side of the first semiconductor layer via an insulating film, and the first semiconductor layer being so configured that a pixel separation insulating film is buried in pixel boundary parts and read transistors for reading signal charges generated by the photoelectric conversion parts are formed at the front side of the first semiconductor layer.

Hereinafter, embodiments will be explained in detail with reference to the accompanying drawings.

### First Embodiment

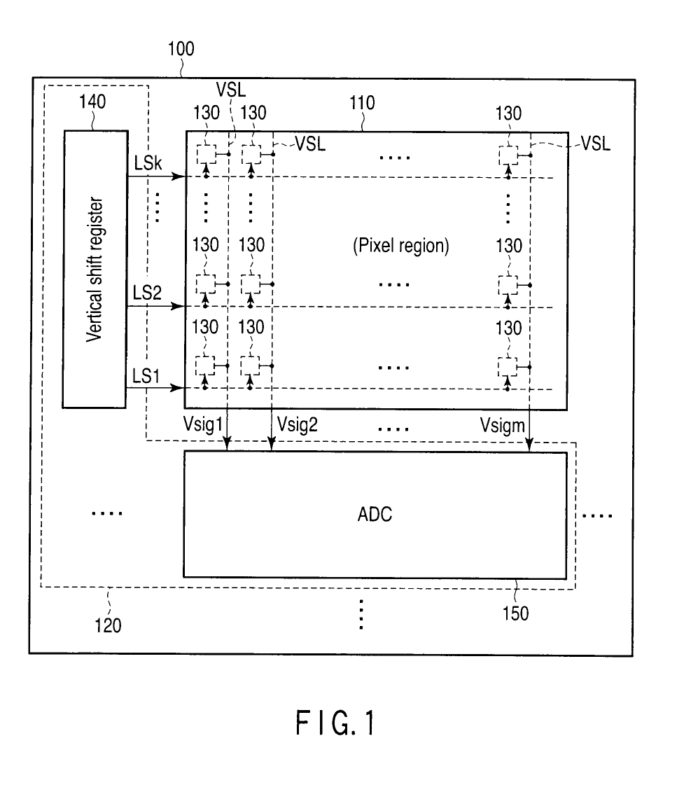

An example of the configuration of a MOS solid-state imaging device according to a first embodiment will be explained with reference to FIGS. 1 to 7. In the first embodiment, an explanation will be given, taking as an example a back-illuminated solid-state imaging device where a light-receiving surface is provided on the back side of a semiconductor substrate opposite the front side of the substrate provided with a signal scanning circuit and others.

FIG. 1 is a system block diagram showing an example of the overall configuration of the MOS solid-state imaging device according to the first embodiment. In FIG. 1, an analog-to-digital conversion circuit (ADC) is arranged in the column position of a pixel array. The solid-state imaging device 100 of the first embodiment comprises an imaging region (pixel array) 110 and a driving circuit region 120.

The imaging region 110 is such that unit pixels are arrayed in a row and a column direction two-dimensionally on a semiconductor substrate, including photoelectric conversion parts and a signal scanning circuit part. The photoelectric conversion parts include unit pixels 130 including photodiodes that convert light into electricity (signal charges) and accumulate signal charges. The photoelectric conversion parts function as imaging parts. The signal scanning circuit part includes amplification transistors 133 and others as described later. The signal scanning circuit part reads a signal from the photoelectric conversion parts, amplifies the signal, and then transmits the amplified signal to an analog-to-digital conversion circuit 150. In the first embodiment, the light-receiving surface (photoelectric conversion parts) is provided on the back side of the semiconductor substrate opposite the front side of the substrate where the signal scanning circuit part is formed.

In the driving circuit region 120, there are provided element driving circuits, including a vertical shift register 140 for driving the signal scanning circuit part and an analog-to-digital conversion circuit 150.

While the analog-to-digital conversion circuit has been a part of the overall configuration of the CMOS sensor, the first embodiment is not limited to this. For instance, the analog-to-digital conversion circuit may not be arranged in the column position of the pixel array and may be arranged in the chip level. Alternatively, the analog-to-digital conversion circuit may not be arranged on the sensor chip.

The vertical shift register 140 outputs signals LS1 to SLk to the pixel array 110 and functions as a selection part for selecting unit pixels 130 on a row basis. Each of the unit pixels 130 in the selected row outputs an analog signal Vsig corresponding to the amount of incident light via a vertical signal line VSL. The analog-to-digital conversion circuit 150 is configured to convert an analog signal Vsig input via the vertical signal line VSL into a digital signal and output the digital signal. Although not shown in FIG. 1, the analog-to-digital conversion circuit 150 includes a CDS noise limiter circuit and the like.

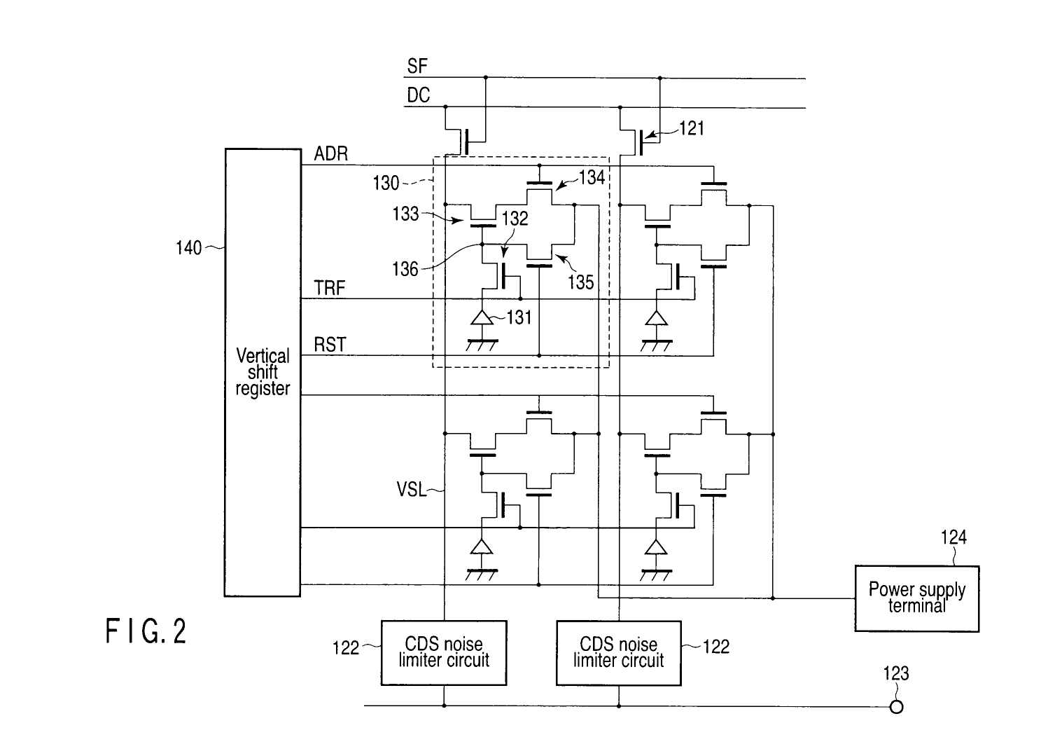

FIG. 2 is an equivalent circuit showing a configuration of the pixel array in the first embodiment. In this case, an explanation will be given, taking an example a single-plate imaging device that acquires a plurality of pieces of color information with the pixel array 110.

As shown in FIG. 2, the pixel array 110 includes a plurality of unit pixels 130 arranged in a matrix at the intersections of the read signal lines from the vertical shift register 140 and the vertical signal lines VSL.

Each of the unit pixels 130 includes a photodiode 131, a read transistor 132, an amplification transistor 133, an address transistor 134, and a reset transistor 135.

The photodiode 131 constitutes a photoelectric conversion part. The amplification transistor 133, reset transistor 135, and address transistor 134 constitute a signal scanning circuit part. The cathode of the photodiode 131 is grounded.

The amplification transistor 133 is configured to amplify a signal from a floating diffusion layer 136 and output the amplified signal. The amplification transistor 133 has its gate connected to the floating diffusion layer 136, its source connected to the vertical signal line VSL, and its drain connected to the source of the address transistor 134. The CDS noise limiter circuit 122 eliminates noise from the output signal of a unit pixel 130 transmitted via the vertical signal line VSL and outputs the resulting signal at an output terminal 123.

The read transistor 132 is configured to control the accumulation of signal charges at the photodiode 131. The read transistor 132 has its gate connected to a read signal line TRF, its source connected to the anode of the photodiode 131, and its drain connected to the floating diffusion layer 136.

The reset transistor 135 is configured to reset the gate potential of the amplification transistor 133. The reset transistor 135 has its gate connected to a reset signal line RST, its source connected to the floating diffusion layer 136, and its drain connected to a power supply terminal 124.

The gate of the address transistor (transfer gate) 134 is connected to an address signal line ADR. The load transistor 121 has it gate connected to a selection signal line SF, its drain connected to the source of the amplification transistor 133, and its source connected to a control signal line DC.

The pixel array structure carries out a read driving operation as follows. First, the address transistor 134 in a row to be read is turned on by a row selection pulse sent from the vertical shift register 140.

Then, the reset transistor 135 is turned on by a reset pulse sent from the vertical shift register 140, resetting the potential of the floating diffusion layer 136. Thereafter, the reset transistor 135 goes off.

Then, the read transistor 132 goes on, causing the signal charges accumulated in the photodiode 131 to be read into the floating diffusion layer 136. The potential of the floating diffusion layer 136 is modulated according to the number of signal charges read.

Then, the modulated signal is amplified by the amplification transistor 133 constituting a source follower and read onto the vertical signal line VSL, which completes the read operation.

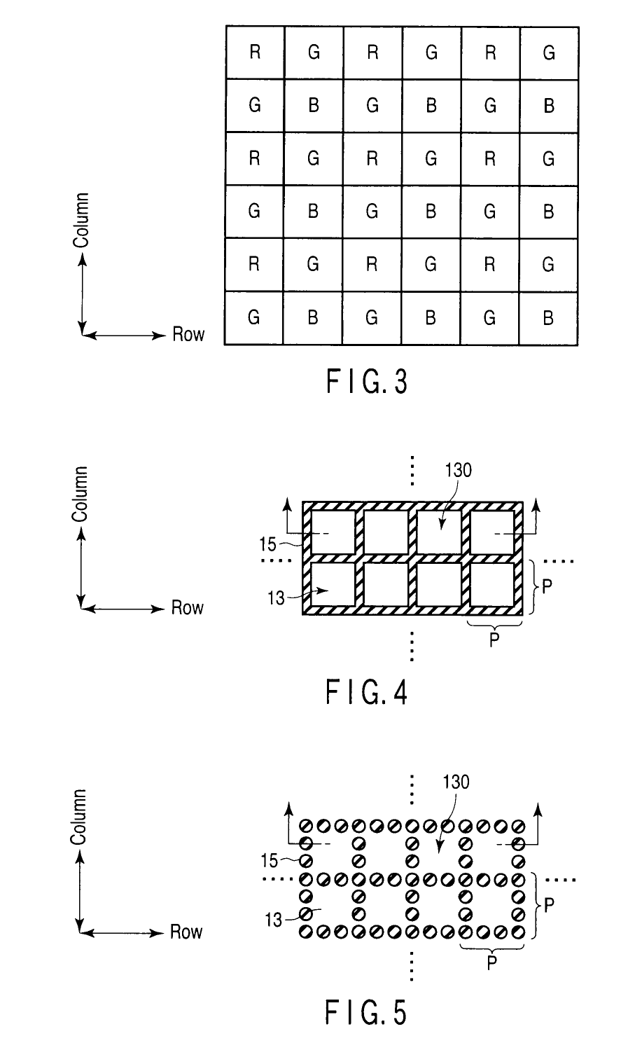

Next, a plane configuration of color filters the solid-state imaging device of the first embodiment has will be explained with reference to FIG. 3. FIG. 3 shows how the color filters are arranged to get color signals in a single-plate solid-state imaging device structure.

In the layout of FIG. 3, a pixel indicated by R is a pixel provided with a color filter that transmits light mostly in the red wavelength region. A pixel indicated by G is a pixel provided with a color filter that transmits light mostly in the green wavelength region. A pixel indicated by B is a pixel provided with a color filter that transmits light mostly in the blue wavelength region.

In the first embodiment, the Bayer arrangement, the most widely used color filter arrangement, is used. As shown in FIG. 3, adjacent color filters (R, G, B) are arranged so as to get color signals differing from one another in the row and column directions.

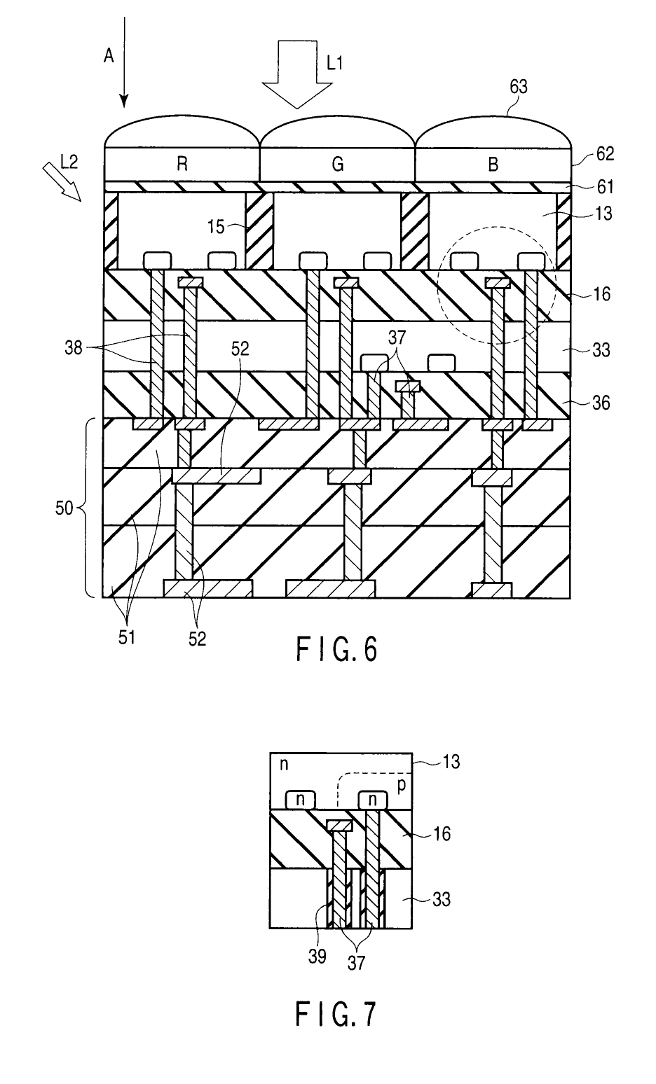

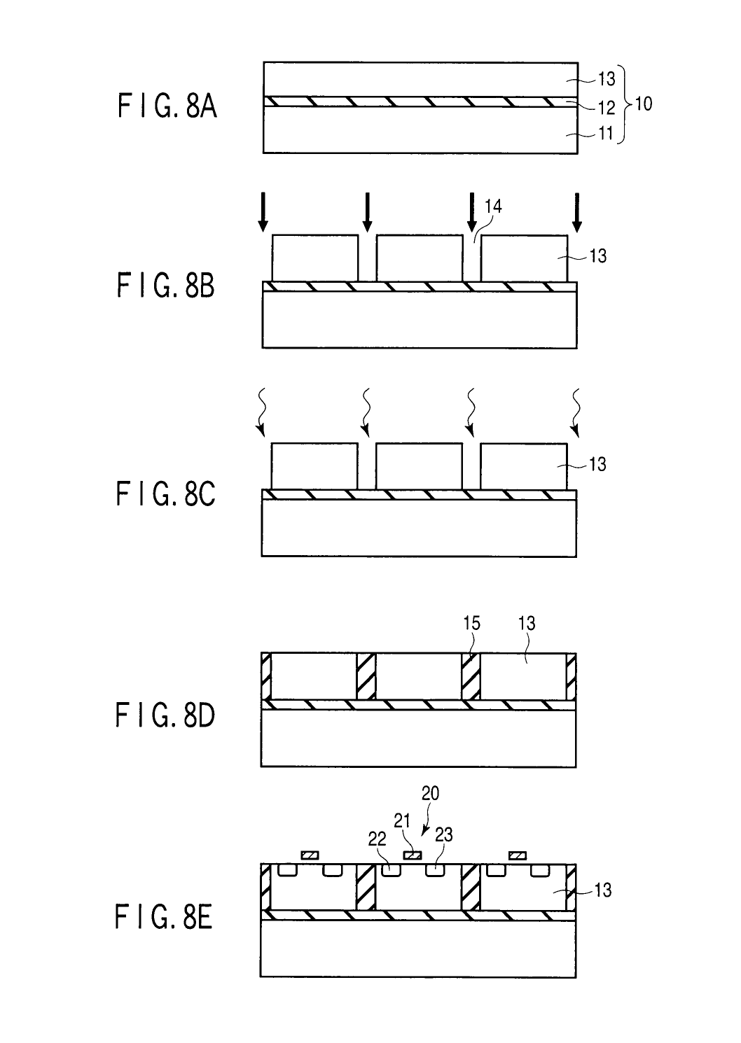

Next, a plane configuration of the pixel array 110 included in the solid-state imaging device of the first embodiment will be explained with reference to FIGS. 4 and 5. An explanation will be given, taking an example a back-illuminated solid-state imaging device where a light-receiving surface is formed on the back side of the semiconductor substrate opposite the front side of the substrate where the signal scanning circuit part composed of the amplification transistor 133 and others is formed.

As shown in FIG. 4, unit pixels 130 are arranged in a matrix in the row and column directions on the back side of a silicon (Si) layer 13. On the Si layer 13, a pixel separation insulating film 15 is provided so as to enclose the boundary part of adjacent unit pixels 130. Specifically, grooves are made so as to pass through the Si layer 13 along the boundary between adjacent unit pixels 130 and the pixel separation insulating film 15 is formed so as to be buried in the grooves. The pixel separation insulating film 15 is provided in a grid pattern so as to surround the unit pixels 130 in the row and column directions.

The pixel separation insulating film 15 is composed of an insulating film whose refractive index is lower than that of Si. For example, it is desirable that the pixel separation insulating film 15 should be made of an insulating material which has a refractive index of about 3.9 or less with respect to incident light whose wavelength is about 400 nm to 700 nm. More specifically, for example, the pixel separation insulating film 15 is made of an insulating material, such as a silicon dioxide film (SiO₂ film), a silicon nitride film (Si₃N₄ film), or a titanium oxide (TiO) film.

As shown in FIG. 4, the unit pixels 130 are arranged in such a manner that the pixel pitch P in each of the row and column directions is the same.

In a plane configuration shown in FIG. 5, the pixel separation insulating film 15 is not continuous along the boundary between adjacent unit pixels 130, but is provided discontinuously along the boundary. Specifically, not continuous grooves but a plurality of through-holes are made in the Si layer 13 and pixel separation insulating films 15 are formed so as to be buried in the through-holes.

While in the first embodiment, the pixel separation insulating films 15 have been provided discontinuously in the through-holes in the plane configuration, some parts of the pixel separation insulating films 15 may be formed continuously.

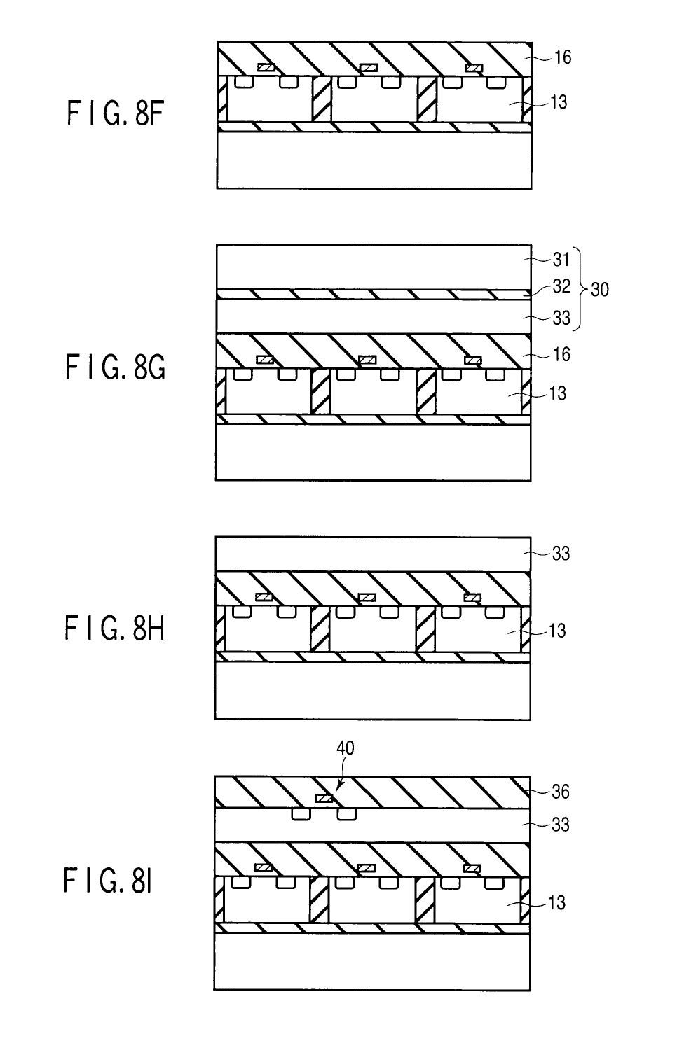

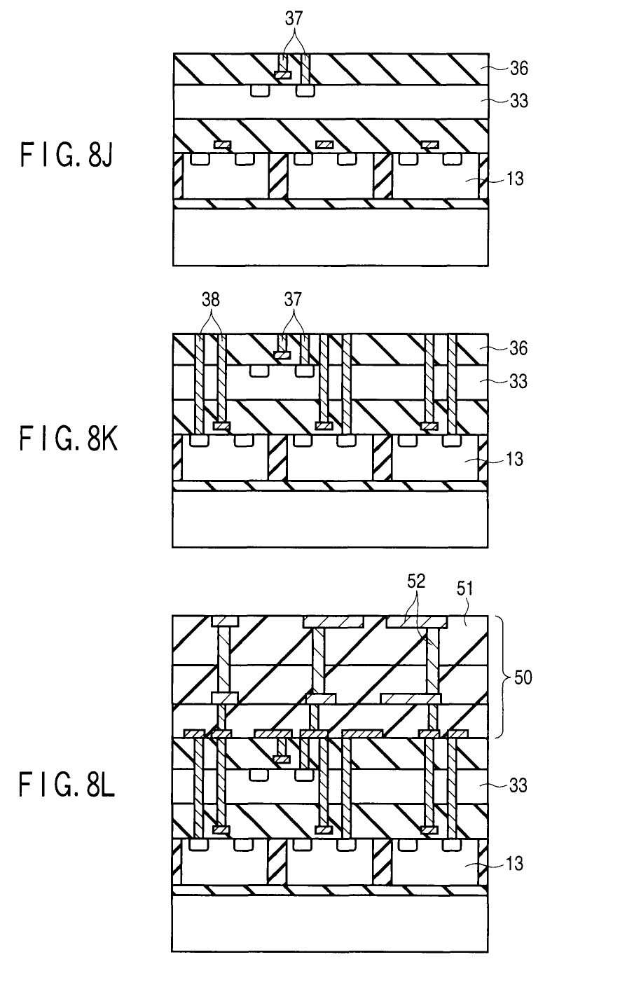

A cross-section configuration of the pixel array 110 included in the solid-state imaging device will be explained with reference to FIGS. 6 and 7. An explanation will be given, taking an example a sectional view taken along line VI-VI of each of FIGS. 4 and 5.

In FIG. 6, a crystalline Si layer (first semiconductor layer) 13 serving as a light-receiving layer is provided in the upper layer in the optical axis direction A and another crystalline Si layer (second semiconductor layer) 33 is provided in the lower layer via an interlayer insulating film 16. In the crystalline Si layer 33, a signal scanning circuit is formed.

More specifically, in the first Si layer 13, a pixel separation insulating film 15 marks off adjacent unit pixels is provided and read transistors are formed at the front side (lower surface) of the Si layer 13. At the front side (lower surface) of the Si layer 13, the second Si layer 33 is formed via the interlayer insulating film 16. In the Si layer 33, the amplification transistor, address transistor, reset transistor, and others are formed to constitute a signal scanning circuit.

On the surface of the Si layer 33, an interlayer insulating film 36 is formed. On the interlayer insulating film 36, an interconnection layer 50 composed of insulating films 51 and metal interconnections 52 is provided. On the back side (upper surface) of the Si layer 13, RGB filters 62 are provided via an Si nitride film 61. Microlenses 63 are formed on the individual filters 62. Incident light L1 enters the back side of the Si layer 13.

To connect the transistors in the Si layer 13 to the transistors in the Si layer 33, via holes 37, 38 are made so as to pass through the Si layer 33 and insulating films 16, 36.

FIG. 7 is an enlarged view of via holes. In FIG. 7, the via holes are made so as to pass through the Si layer 33. To prevent metal vias 37 constituting the via holes from short-circuiting with the Si layer 33, an insulating film 39 is formed between the metal vias 37 and the Si layer 33.

As shown in FIG. 6, the pixel separation insulating film 15 is formed at the boundary region between pixels. The light-receiving layer and signal scanning circuit layer are formed in separate Si layers, with the result that only photodiodes and read gates are formed in the light-receiving layer. Therefore, the grooves or holes in the pixel separation region can be processed from the same surface as the active element forming surface.

Next, the optical effect of the solid-state imaging device of the first embodiment will be explained with reference to FIG. 6. As described above, the pixel separation insulating film 15 that sectionalizes the pixel separation region is provided in the Si layer 13 so as to enclose the boundary part between adjacent unit pixels 130 in the solid-state imaging device. This configuration produces the following optical effect.

With a configuration without the pixel separation insulating film 15, light L2 obliquely entering the light-receiving region of the Si layer goes toward adjacent unit pixels, cross the boundary between pixels, and enters the adjacent unit pixels. As a result, this causes photoelectrons to be generated in the adjacent unit pixels, permitting crosstalk and color mixture to take place. Therefore, the color reproducibility is deteriorated on the replay screen.

In contrast, as shown in FIG. 6, with the configuration of the first embodiment, light L2 that enters obliquely is reflected by the pixel separation insulating film 15, preventing light from entering the adjacent unit pixels. Therefore, this prevents crosstalk and color mixture from taking place.

When pixels are miniaturized, the aperture pitches of the microlenses 63 and color filters 62 decrease, which permits diffraction to take place particularly when light entering R pixels corresponding to the long-wavelength passes through the color filter 62. In this case, light L2 obliquely entering the light-receiving region in the Si layer 13 goes toward adjacent pixels, crosses the boundary between adjacent pixels, and enters the adjacent pixels. Light entering the adjacent pixels generates photoelectrons in the adjacent pixels, causing crosstalk, which permits color mixture to take place. Therefore, the color reproducibility is deteriorated on the replay screen, which degrades the image quality. In contrast, with the first embodiment, even when light enters the long-wavelength R pixels, crosstalk and the generation of color mixture can be prevented.

With the first embodiment, as shown in FIG. 6, since the pixel separation insulating film 15 is provided at the boundary part between adjacent unit pixels 130, light L2 that enters obliquely is reflected by the pixel separation insulating film 15, which prevents light entering the unit pixels 130 from entering the adjacent unit pixels. Accordingly, crosstalk and color mixture are prevented, which is effective in improving the color reproducibility on the replay screen.

In addition, since the solid-state imaging device is of the back-illuminated type, light can enter the back side of the Si substrate opposite the front side of the substrate where the signal scanning circuit and its interconnection layer have been formed. Therefore, light entering the pixels can reach a light-receiving region formed in the Si layer without being impeded by the interconnection layer, making it possible to realize high quantum efficiency even when pixels are very small. As a result, this offers the advantage of suppressing the deterioration of the quality of reproduced images even when pixels are miniaturized further.

Furthermore, since not only are the light-receiving region and signal scanning circuit provided in the separate Si layers, but also the read transistor 32 is provided in the Si layer 13 acting as a light-receiving layer, signal electrons are read from the photodiode 31 in the crystalline Si layer. Therefore, no signal charge will be left over in a read operation. Accordingly, neither afterimages nor kTC noise is generated, enabling images to be reproduced with low noise.

### Second Embodiment

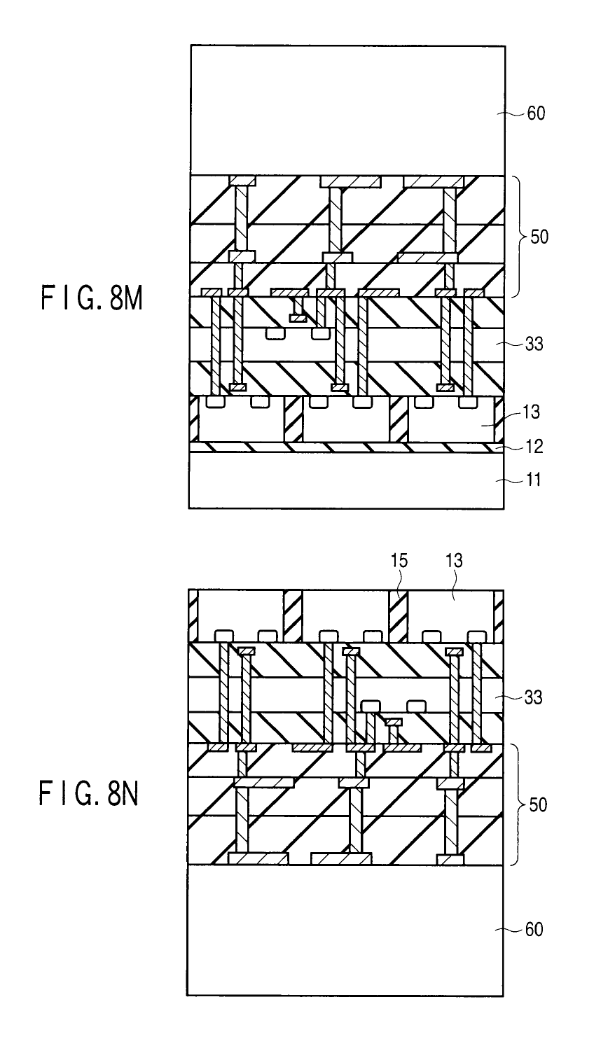

Next, a method of manufacturing the MOS back-solid-state imaging device of FIG. 6 will be explained with reference to FIGS. 8A to 8N.

FIGS. 8A to 8N are sectional views to explain the manufacturing processes for producing the structure of FIG. 6. In this example, an Si substrate is such that an SiO₂ insulating film is formed on a crystalline Si and a so-called silicon-on-insulator (SOI) structure is provided on the insulating film

First, as shown in FIG. 8A, an SOI substrate 10 where an Si layer (first Si layer) 13 has been formed above an Si substrate 11 via a buried insulating layer 12 is prepared.

Next, as shown in FIG. 8B, after a pixel separation pattern mask (not shown) is formed on the surface of the Si layer 13, grooves (or holes) 14 are made by etching a part of the Si layer 13 from the front side of the Si layer 13, that is, the opposite side of a light-receiving region.

Then, as shown in FIG. 8C, dopant is introduced into the Si surface enclosed with the grooves in the Si layer 13 (side surface portion of grooves 14) by solid-phase diffusion or other means, thereby forming a p-type region.

Next, as shown in FIG. 8D, an insulating film 15 is buried in the grooves 14 formed as a pixel separation structure by CVD, spin coat techniques, or the like. The refractive index of the insulating film 15 is lower than that of Si.

Next, as shown in FIG. 8E, an n-type diffusion layer 22 constituting a photodiode and n-type diffusion layer 23 constituting a floating diffusion layer are formed in the Si layer so as to be separated from each other. In addition, a MOS gate electrode 21 made of polysilicon is formed on a channel region between layers 22. 23. That is, a MOS transistor composed of the gate electrode 21 and diffusion layers 22, 23 is formed. The transistor functions as a read transistor which reads signal charges when the device is operating.

Next, as shown in FIG. 8F, an insulating film 16 composed of a TEOS film or the like is deposited on the surface of the Si layer 13.

Then, as shown in FIG. 8G, an SOI substrate 30 where an Si layer (second Si layer) 33 has been formed above an Si substrate 31 via a buried insulating film 32 is prepared and the Si layer 33 is caused to adhere to the insulating film 16.

Next, as shown in FIG. 8H, of the laminated SOI substrates, the Si substrate 31 and insulating film 32 are removed and only the Si layer 33 is left on the insulating film 16.

Next, as shown in FIG. 8I, an n-type diffusion layer and MOS gate are formed at the surface of the Si layer 33 in the same method as described above. As a result, a row select transistor, an amplification transistor, and a reset transistor are formed. The above-mentioned each transistor works as signal scanning circuit at the element operation. Then, an insulating film 36 made of TEOS or the like is deposited on the Si layer 33.

Then, as shown in FIG. 8J, via holes are made in the insulating film 36 in the top layer and Si through vias 37 are formed so as to fill up the via holes.

Next, as shown in FIG. 8K, via holes connected to the gate of the Si layer 13 and diffusion layer and Si through vias are formed.

Next, as shown in FIG. 8L, on the insulating film 36 in which the via holes and Si through vias 37, 38 have been formed, an interconnection layer 50 composed of an insulating film 51, metal interconnections 52, and others is formed.

Then, as shown in FIG. 8M, a support substrate 60 made of Si or the like is laminated onto the interconnection layer 50. Thereafter, as shown in FIG. 8N, the Si substrate 11 and insulating film 12 are peeled from the Si layer 13. Then, color filters and microlenses are formed on the light-receiving surface, the back side of the Si layer 13, thereby producing the structure shown in FIG. 6.

As described above, with the second embodiment, after the grooves for pixel separation are made and the insulating film is buried in the grooves in the SOI substrate 10, the read transistors are formed in the Si layer 13 and the substrate 11 of the SOI substrate is finally removed as shown in FIGS. 8A to 8N. Accordingly, the process of causing the Si layer 13 to adhere to another support substrate temporarily to make pixel separation grooves becomes unnecessary and therefore the manufacturing process can be simplified.

### Modification

This invention is not limited to the above embodiments. While in the embodiments, an SOI substrate has been used to form a first Si layer, the SOI substrate is not necessarily used, provided that any suitable auxiliary substrate is used as a substrate for the Si layer. For instance, after an Si substrate is caused to adhere to an auxiliary substrate, the Si substrate may be made thinner, thereby forming a first Si layer. In this case, the first Si layer is formed on the auxiliary substrate. Then, various processes are carried out as in the above embodiments to finally remove the auxiliary substrate.

Furthermore, a semiconductor substrate for forming photoelectric conversion parts is not necessarily limited to Si and other semiconductor materials may be used instead. In addition, the insulating film materials for various parts, the interconnection materials, and others may be changed suitably according to the specification. In the embodiments, a so-called type of four transistors including the address transistor was described as the signal scanning circuit part, it can apply to the type of three transistors where the address transistor is not comprised either.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device with an array arrangement of unit pixels,
each of the unit pixels comprising:
a photoelectric conversion part provided in a first semiconductor layer and receiving light that enters the back side of the semiconductor layer and generates signal charges, and
a signal scanning circuit part which outputs signal charges obtained at the photoelectric conversion part and which is provided in a second semiconductor layer stacked above the front side of the first semiconductor layer via an interlayer insulating film,
wherein the first semiconductor layer being so configured that a pixel separation insulating film is buried in a pixel boundary part and a read transistor configured to read signal charges generated at the photoelectric conversion part is formed on its front side.

2. The device according to claim 1, wherein the pixel separation insulating film is provided to pass through the first semiconductor layer in the thickness direction.

3. The device according to claim 1, wherein the pixel separation insulating film has a lower refractive index than that of the first semiconductor layer.

4. The device according to claim 1, wherein the pixel separation insulating film is provided continuously along the pixel boundary.

5. The device according to claim 1, wherein the pixel separation insulating film is provided discontinuously along the pixel boundary.

6. The device according to claim 1, wherein the signal scanning circuit part is composed of an amplification transistor configured to amplify signal charges read by the read transistor, and a reset transistor configured to reset the gate potential of the amplification transistor.

7. The device according to claim 6, wherein the amplification transistor and the reset transistor are provided on one side of the second semiconductor layer opposite the first semiconductor layer.

8. The device according to claim 1, wherein the back side of the first semiconductor layer is provided with color filters and microlenses.

9. A solid-state imaging device comprising:
a first silicon layer which has a front side and a back side opposite the front side and which allows light to enter the back side;
a pixel separation region formed by burying in the first silicon layer an insulating film whose refractive index is lower than that of the first silicon layer to separate the first silicon layer pixel by pixel;
photoelectric conversion parts which are provided in the individual regions separated by the pixel separation region in the first silicon layer in a one-to-one correspondence and which generate signal charges by photoelectric conversion;
read transistors provided on the front side of the individual regions separated by the pixel separation region in the first silicon layer in a one-to-one correspondence and reading signal charges generated by the photoelectric conversion parts;
a second silicon layer stacked above the front side of the first silicon layer via an interlayer insulating film; and
a signal scanning circuit provided in the second silicon layer and outputting a signal read by the read transistor to the outside.

10. The device according to claim 9, wherein the pixel separation region is provided to pass through the first silicon layer in the thickness direction.

11. The device according to claim 9, wherein the pixel separation region is provided continuously along the boundary between pixels.

12. The device according to claim 9, wherein the pixel separation region is provided discontinuously along the boundary between pixels.

13. The device according to claim 9, wherein the signal scanning circuit is composed of an amplification transistor configured to amplify signal charges read by the read transistor, and a reset transistor configured to reset the gate potential of the amplification transistor.

14. The device according to claim 13, wherein the amplification transistor and the reset transistor are provided on one side of the second silicon layer opposite the first silicon layer.

15. The device according to claim 9, wherein the interlayer insulating film is provided with through vias for electrically connecting the read transistors to the signal scanning circuit.

16. The device according to claim 9, wherein one side of the second silicon layer opposite to the first silicon layer is provided with an interconnection layer composed of an insulating film and metal interconnections.

17. The device according to claim 9, wherein the back side of the first silicon layer is provided with color filters and microlenses.

18. A method of manufacturing a solid-state imaging device, comprising:
forming in a first semiconductor layer, photoelectric conversion parts configured to generate signal charges by photoelectric conversion, a pixel separation region composed of an insulating film which separates the photoelectric conversion part into pixels, and read transistors configured to read signal charges generated by the individual photoelectric conversion parts separated by the pixel separation region;
stacking a second semiconductor layer above the front side of the first semiconductor layer via an interlayer insulating film; and
forming in the second semiconductor layer a signal scanning circuit configured to output a signal read by the read transistor.

19. The method according to claim 18, wherein
the photoelectric conversion parts are formed in the first semiconductor layer, the pixel separation region is formed to pass through the front side and back side of the first semiconductor layer, and the read transistors are formed on the front side of the first semiconductor layer.

20. The method according to claim 18, wherein the signal scanning circuit is provided on one side of the second semiconductor layer opposite to the first semiconductor layer.
